(19) United States
(12) Patent Application Publication
(10) Pub. No.: US 2007/0246821 A1
(43) Pub. Date: Oct. 25, 2007

(54) Utra-thin substrate package technology

(76) Inventors: Szu Wei Lu, HsinChu (TW); Clinton Chao, Hsinchu (TW); Tjandra Winata Karta, Hsinchu (TW); Jerry Tzou, Hsinchu (TW); Kuo-Chin Chang, HsinChu (TW)

Correspondence Address: SLATER & MATSIL, L.L.P., 17950 PRESTON ROAD, SUITE 1000, DALLAS, TX, 75252, US

(21) Appl. No.: 11/408,155

(22) Filed: Apr. 20, 2006

(51) Int. Cl. H01L 23/48; H01L 29/40

(52) U.S. Cl. 257/701; 438/108; 438/125; 438/459; 438/464; 438/612; 257/778; 257/784; 257/738

(57) ABSTRACT

A semiconductor package assembly having reduced stresses and a method for forming the same are provided. The method includes providing a package substrate comprising a base material, forming an interconnect structure overlying the package substrate, attaching at least one chip to a first surface of the package substrate, thinning the package substrate from a second surface opposite the first surface wherein the semiconductor material is substantially removed, and attaching ball grid array (BGA) balls to deep vias exposed on the second surface of the package substrate after thinning the package substrate.

### TECHNICAL FIELD

This invention relates generally to the packaging of integrated circuits, and more particularly to materials and methods for reducing stresses in packages.

### BACKGROUND

The fabrication of modern circuits typically includes several steps. Integrated circuits are first fabricated on a semiconductor wafer, which contains multiple duplicated semiconductor chips, each comprising integrated circuits. The semiconductor chips are then cut from the wafer and packaged. The packaging processes have two main purposes: protecting delicate semiconductor chips and connecting interior integrated circuits to exterior pins.

In conventional packaging processes, semiconductor chips are mounted on an organic module substrate through flip-chip bonding or wire bonding. Underfill is dispensed into the gaps (between the chips and the substrate) to prevent cracks in solder bumps or solder balls, wherein cracks are typically caused by thermal stresses.

The conventional packaging processes, however, suffer drawbacks. High stress, which is partially induced by a high mismatch of the coefficients of thermal expansion (CTE) between silicon semiconductor chips and package substrates, is generated. There are several major reliability concerns caused by stress. Firstly, stress impacts the reliability of low-k and extreme low-k material in semiconductor chips. Secondly, stress impacts the reliability of lead-free packages, in which lead-free solder bumps are used. Lead-free bumps are highly recommended by the packaging industry for their low pollution. However, lead-free bumps are too brittle and are prone to cracking. Currently used underfills cannot provide adequate protection for lead-free bumps.

The stress problem is further worsened by the increase in package size. Due to the shortened connecting paths between components, greater package size brings in the benefit of improved electrical performance. However, greater package size also results in greater stress, and in turn causes several package concerns during packaging processes and reliability tests.

Advanced substrates, such as organic substrates, which are increasingly used in the packaging industry, are beneficial for cost reduction. However, organic substrates also come with performance loss due to routing limitations, defeating the purpose of increasing the package size for the electrical performance improvement.

Accordingly, what is needed in the art is a structure and/or a method for system in chip (SiP) packages to take advantage of the benefits associated with a greater degree of integration while at the same time overcoming the deficiencies of the prior art.

### SUMMARY OF THE INVENTION

In accordance with one aspect of the present invention, a method for forming a packaging assembly having reduced stress includes providing a package substrate comprising a base material, forming an interconnect structure overlying the package substrate wherein the interconnect structure comprises deep vias at the bottom of the interconnect structure, attaching at least one chip to a first surface of the package substrate, thinning the package substrate from a second surface opposing the first surface wherein a substantial portion of the base material is removed, and attaching ball grid array (BGA) balls to deep vias exposed on the second surface of the package substrate after thinning the package substrate.

In accordance with another aspect of the present invention, the step of forming the interconnect structure includes forming a dielectric layer over the base material, forming deep vias adjacent to a top surface of the base material, forming a plurality of dielectric layers over the dielectric layer, forming a plurality of metallization layers and a plurality of vias in the dielectric layers, wherein the metallization layers and vias are interconnected and connected to the deep vias, and forming a plurality of contact pads electrically connected to the metallization layers wherein the contact pads are electrically connected to the at least one chip.

In accordance with yet another aspect of the present invention, a semiconductor assembly includes a die mounted on a first surface of a package substrate, and BGA balls attached on a second surface of the package substrate opposing the first surface, wherein the package substrate has a thickness of less than about 50 μm. The interconnect structure preferably includes a dielectric layer, deep vias in the dielectric layer, wherein the deep vias are attached to the BGA balls, a plurality of dielectric layers over the dielectric layer, a plurality of metallization layers and a plurality of vias connected to the metallization layers in the dielectric layers wherein the metallization layers are interconnected and connected to the deep vias, and a plurality of contact pads connected to the metallization layers, wherein the contact pads are electrically connected to the die through conductive wires or bumps.

The advantageous features of the preferred embodiments of the present invention include reduced stress on the bumps and low-k dielectric layers in dies due to the ultra-thin package substrate, and improved electrical performance due to the flexible routing scheme in the package substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a typical flip-chip package;

FIGS. 2, 3A and 3B show the normalized stresses applied on BGA balls and low-k dielectric material in the dies as functions of the thickness of the package substrate, respectively.

FIG. 4 illustrates a flow-chart of the preferred embodiment of the present invention, wherein a flip-chip package is formed;

FIGS. 5 through 8B illustrate intermediate stages in the manufacture of a flip-chip package with an ultra-thin package substrate;

FIG. 9 illustrates a flow-chart of the preferred embodiment of the present invention, wherein a wire bonding package is formed; and

FIGS. 10a through 12 illustrate intermediate stages in the manufacture of a wire-bonding package with an ultra-thin package substrate.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for packaging semiconductor chips with an ultra-thin package substrate is provided. The intermediate stages of manufacturing the preferred embodiment of the present invention are illustrated. The variations of the preferred embodiments are then discussed. Throughout the various views and illustrative embodiments of the present invention, like reference numbers are used to designate like elements.

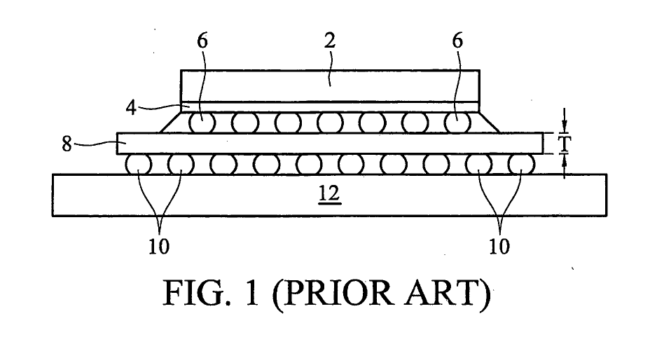

Stresses in a package are related to various factors, such as the material of the underfill, the thickness of the semiconductor chip, etc. FIG. 1 illustrates a typical flip-chip package. A semiconductor chip (also referred to as a die in the packaging art) 2, which comprises at least a low-k material (ILD or IMD) 4, is flip-mounted on a package substrate 8 through bumps 6. The package substrate 8 is then assembled to a printed circuit board (PCB) 12 through ball grid array (BGA) balls 10. The package substrate 8 has a thickness T.

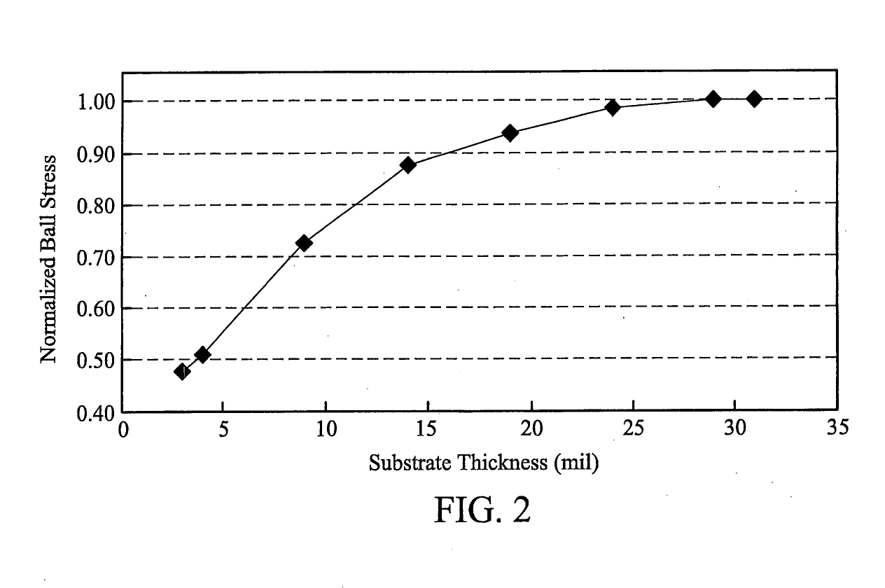

A simulation has been performed to reveal the relationship between thickness T of the package substrate 8 and the stresses applied on low-k material 4, bumps 6 and BGA balls 10. FIG. 2 illustrates normalized ball stress as a function of substrate thickness T, wherein ball stress at a package substrate thickness of 31 mils is used as a normalization base. It has been found that stress applied on BGA balls 10 decreases when the substrate thickness T is decreased. When substrate thickness T is reduced from 31 mils to 3 mils, the stress applied on BGA balls 10 is reduced by 52%.

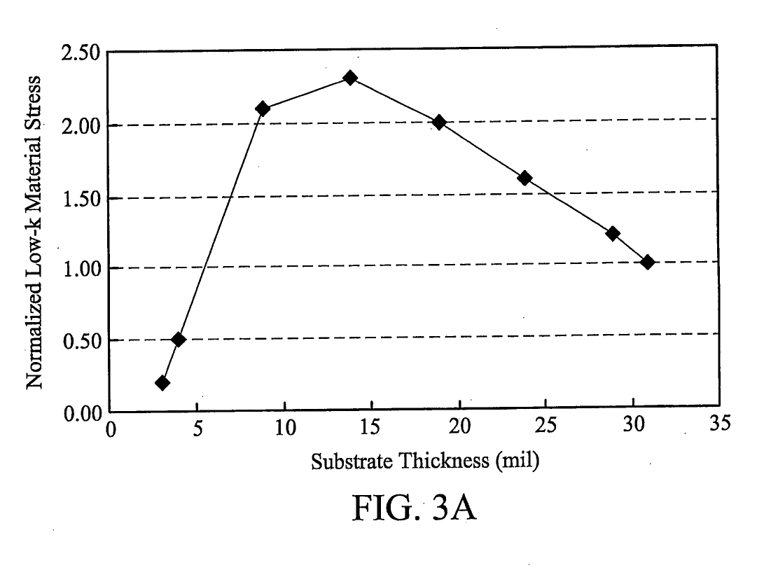

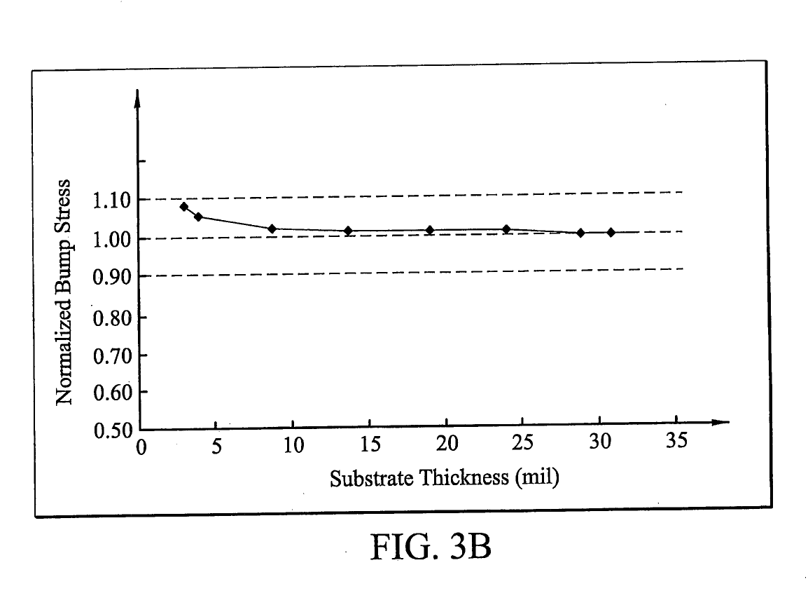

FIG. 3A illustrates normalized stress applied on low-k material 4 as a function of substrate thickness T. It has been found that as the substrate thickness T is reduced from 31 mils to 3 mils, the stress applied on low-k material 4 first increases, reaching a peak at about 14 mils. When the substrate thickness T continues to decrease, the stress decreases. When the substrate thickness T is reduced to 3 mils, the stress decreases to about 20% of the stress when the substrate thickness T was 31 mils. Therefore, to reduce the stress applied on low-k material 4, the substrate thickness T needs to be lower than a certain threshold thickness, which is about 14 mils in this simulation sample.

Stress applied on bumps 6, however, increases when the substrate thickness T decreases. As shown in FIG. 3B, simulation results also reveal that when substrate thickness T decreases from 31 mils to 3 mils, stress applied on bumps 6 increases by about 8%. Compared to the decrease of stresses applied on the BGA balls and the low-k material 4 (52% and 80%, respectively), this increase is not significant.

A conclusion can be drawn from the simulation results that thin package substrates are desirable for reducing the overall stresses in packages. It is more desirable that the substrate thickness T be less than a threshold thickness to avoid the possible occurrence of a stress peak at the low-k dielectric material. Conventionally, however, ultra-thin package substrates are not used. One of the reasons is that ultra-thin package substrates are prone to breaking. A new ultra-thin package substrate structure and a method for forming and handling the same, therefore, are provided by the preferred embodiments of the present invention.

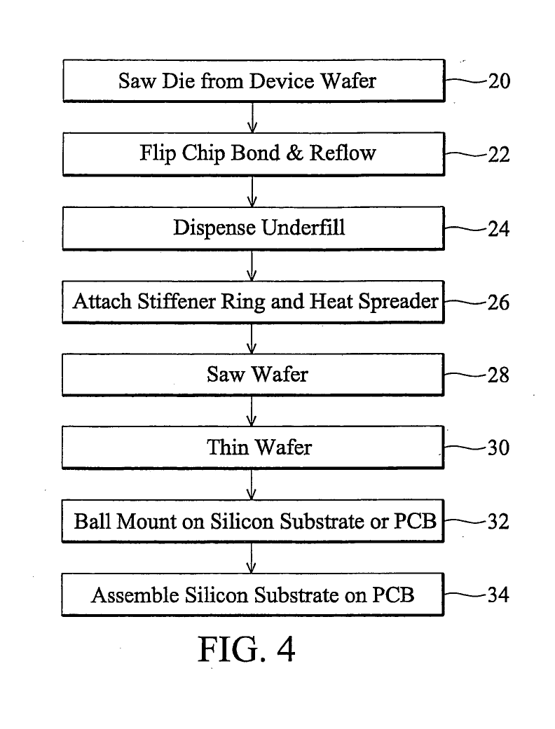

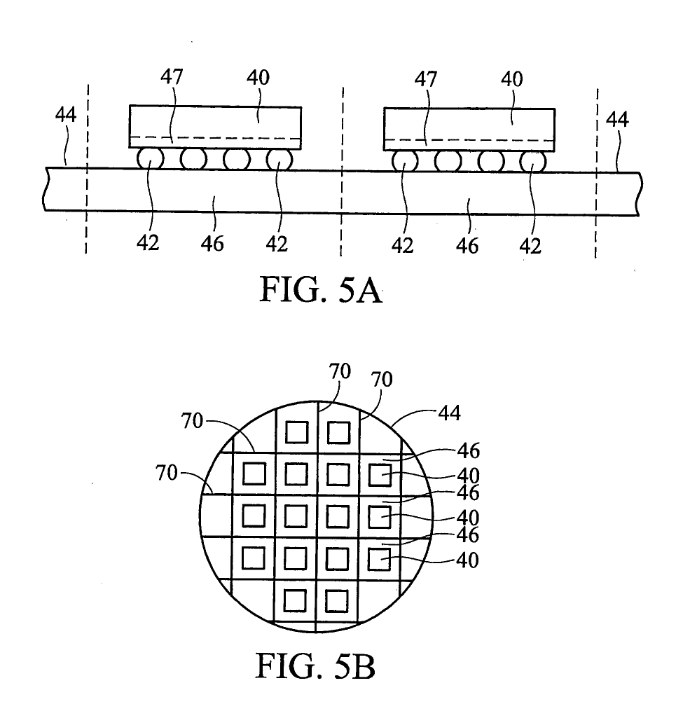

FIGS. 4 through 8B illustrate a flip-chip packaging process. FIG. 4 shows a flow-chart of the preferred method. As step 20 indicates, dies (semiconductor chips) are first sawed from a device wafer. The dies preferably comprise at least one low-k dielectric layer (refer to dielectric layer 47 in FIG. 5A), and more preferably more than one low-k dielectric layer; for example, inter-layer dielectric (ILD) and inter-metal dielectric (IMD) layers. The low-k dielectric layer preferably has a k value of less than about 3.0.

The dies 40 are then flip bonded to a wafer 44, which includes multiple package substrates 46, through bumps 42. A cross-sectional view is shown in FIG. 5A. Each die 40 is attached to a package substrate 46, which is a portion of the wafer 44. In the preferred embodiment, bumps 42 are lead-free. In other embodiments, bumps 42 comprise less than about five percent lead. In yet other embodiment, bumps 42 are eutectic bumps. A reflow is then performed to shape bumps 42 (step 22 in FIG. 4). FIG. 5B illustrates a top view of the structure shown in FIG. 5A.

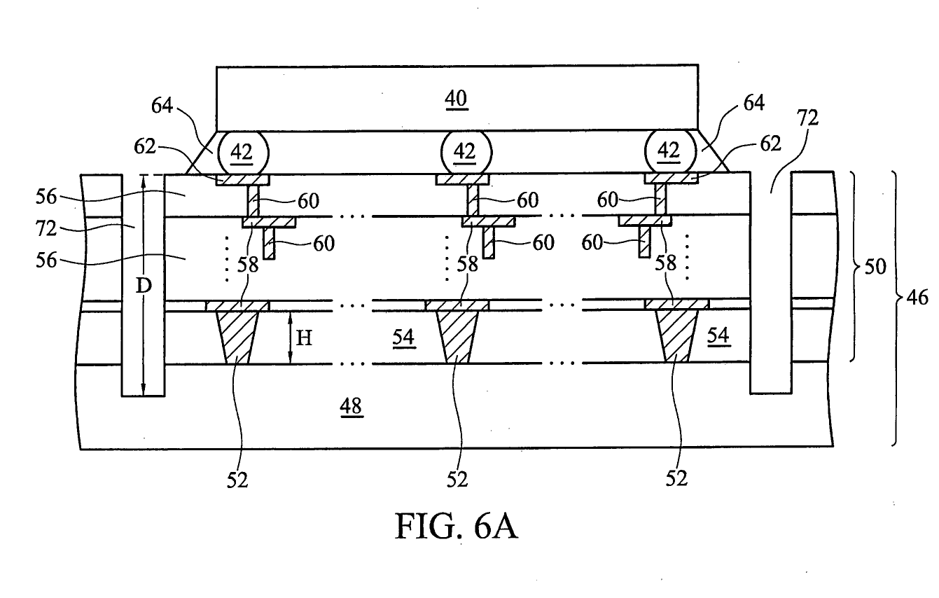

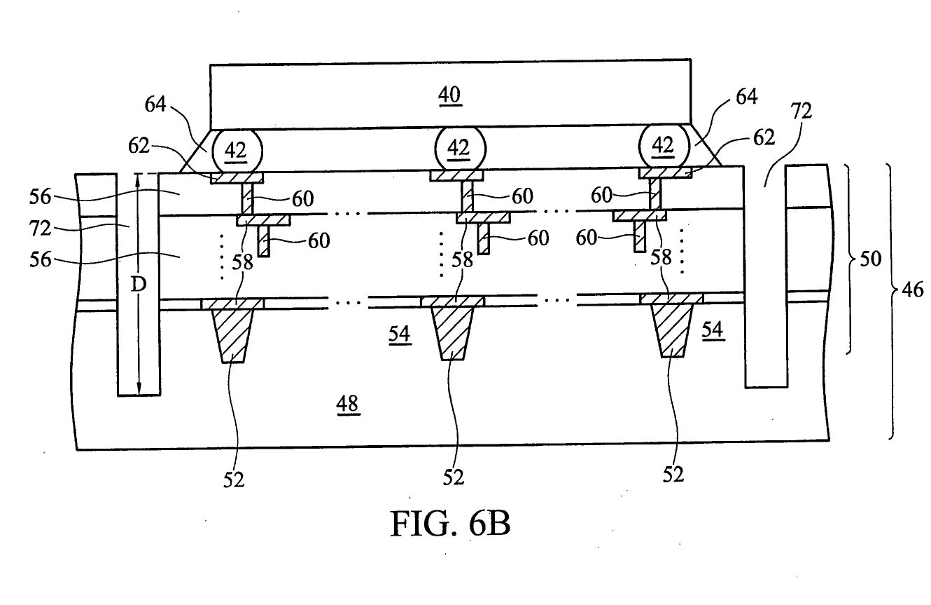

FIG. 6A illustrates a cross-sectional view of the package substrate 46 and the flip-mounted die 40. The package substrate 46 comprises a base layer 48 and an interconnect structure 50. Note that the scale of the interconnect structure 50 may be greater than the actual value in order to show details. Preferably, base layer 48 comprises a semiconductor material, and more preferably silicon. Base layer 48 may also be formed from dielectric materials such as glass. The interconnect structure 50 comprises deep vias 52, which are conductive, in a first dielectric layer 54. Deep vias 52 are preferably arranged as a grid, and the locations of the deep vias preferably correspond to the BGA balls that are to be attached to deep vias 52 in subsequent steps. Deep vias 52 have a preferred height H of between about 1 μm and about 10 μm, and a pitch of between about 300 μm and about 1000 μm. The interconnect structure 50 preferably has a thickness of less than about 50 μm, and more preferably less than about 10 μm.

A plurality of dielectric layers 56 are formed over the deep vias 52 and dielectric layer 54. The number of dielectric layers 56 partially depends on the requirement for routing conductive paths between deep vias 52 and pads 62. In the preferred embodiment, at least two dielectric layers 56 are formed. Dielectric layers 56 preferably have a high mechanical strength. The preferred materials include SiN, SiO₂, spin on glass (SOG), and the like. In the preferred embodiment, dielectric layers 56 are formed using chemical vapor deposition (CVD). In other embodiments, commonly used methods such as spin coating and printing can be used.

Metallization layers, each comprising a plurality of metal lines 58, are formed in the respective dielectric layers 56. Vias 60 are formed in the dielectric layers 56, interconnecting metal lines 58 in different metallization layers. Vias 60 and overlying metallization layers can be formed using dual damascene or single damascene processes, as is known in the art. Through the interconnect structure 50, deep vias 52 are connected to pads 62, which are exposed on the top of the package substrate 46. The deep vias 52, metal lines 58 and vias 60 preferably comprise conductive materials such as copper, tungsten, aluminum, and combinations thereof. The formation process for the deep vias 52, dielectric layers 56, vias 60 and pads 62 are well known in the art, and thus are not repeated herein.

In the preferred embodiment shown in FIG. 6A, deep vias are formed in a dielectric layer over base layer 48. In alternative embodiments, as shown in FIG. 6B, deep vias 52 have at least a portion formed in base layer 48. The formation process preferably includes forming deep trenches in the base layer 48, preferably by etching, and filling the deep trenches with conductive materials such as aluminum, silver, tungsten, titanium, and combinations thereof. Base layer 48 preferably has a low conductivity, and is preferably formed of a semiconductor material, such as silicon, SiGe, and the like, or a dielectric material. Excess materials are then removed, preferably by using a chemical mechanical polish. The remaining conductive materials form deep vias 52. Metal lines 58 may be formed directly on deep vias 52, or in a metallization layer overlying the base layer 48. Vias (not shown) may be formed to connect the deep vias 52 and metal lines 58.

A die 40 is flip-mounted on package substrate 46 with pads 62 attached to bumps 42. Underfill 64 is dispensed into the gaps formed by die 40, package substrate 46 and bumps 42 (step 24 in FIG. 4), and provides structural support to bumps 42.

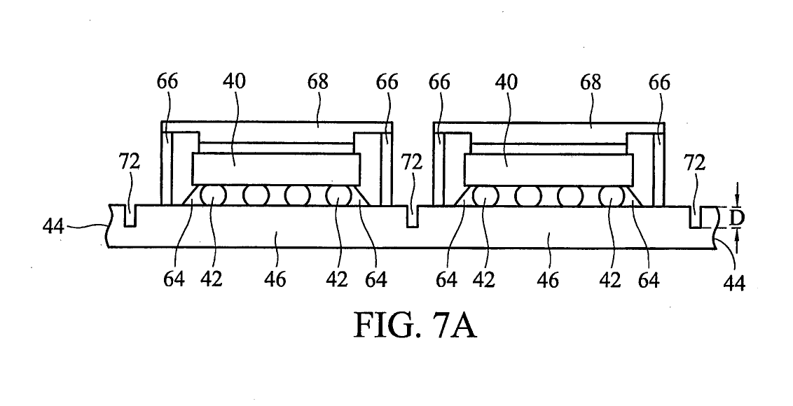

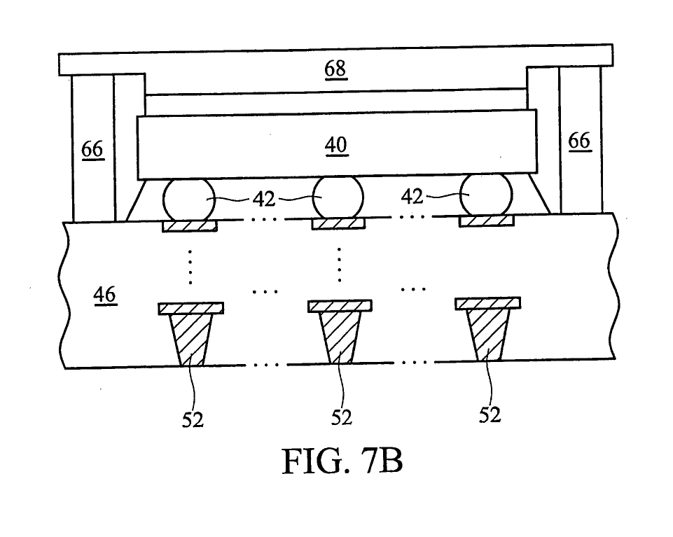

Referring to FIG. 7A, stiffener rings 66 and heat spreaders 68 are placed (step 26 in FIG. 4). Each of the stiffener rings 66 encircles a die 40, bumps 42 and underfill 64, providing further support to the die 40, bumps 42, and package substrate 46. The heat spreaders 68 are mounted on the dies 40 for better heat dissipation.

The wafer 44 is then sawed along scribe lines 70 (step 28 in FIG. 4, also refer to FIG. 5B). Preferably, only shallow trenches 72 are formed along the scribe lines, and the package substrates 46 are still attached to each other, as shown in FIG. 7A. The trenches 72 preferably have a depth D (refer to FIGS. 6A, 6B and 7A) of less than about 50 μm, or even less than about 10 μm, depending on the thickness of the interconnect structure 50. More preferably, the depth D is slightly greater than the thickness of the interconnect structure 50.

A protection tape (not shown), which provides mechanical support to the wafer 44 during subsequent etching/polishing processes, is applied on the top surface (the side with dies 40 attached thereon) of the wafer 44. Wafer 44 is then thinned from the bottom surface (step 30 in FIG. 4). The thinning of the package substrate preferably comprises etching, polishing and chemical mechanical polish (CMP).

Referring back to FIG. 6A, the base layer 48 is completely removed by the thinning process. In FIG. 6B, a bottom portion of the base layer 48 below bottom surfaces of the deep vias 52 are removed. Deep vias 52 are thus exposed from the bottom surface of the remaining package substrate 46, which now contains only the interconnect structure 50. Since the interconnect structure 50 has a thickness of less than about 50 μm, the resulting package substrate 46 is ultra-thin with a preferred thickness of less than about 50 μm, and more preferably less than about 10 μm.

Since the depth D of the trenches 72 is greater than the thickness of the interconnect structure 50, when base layer 48 is removed, package substrates 46 are disconnected. After the protection tape is removed, package substrates 46 are separated into individual pieces. A package substrate 46 is shown in FIG. 7B.

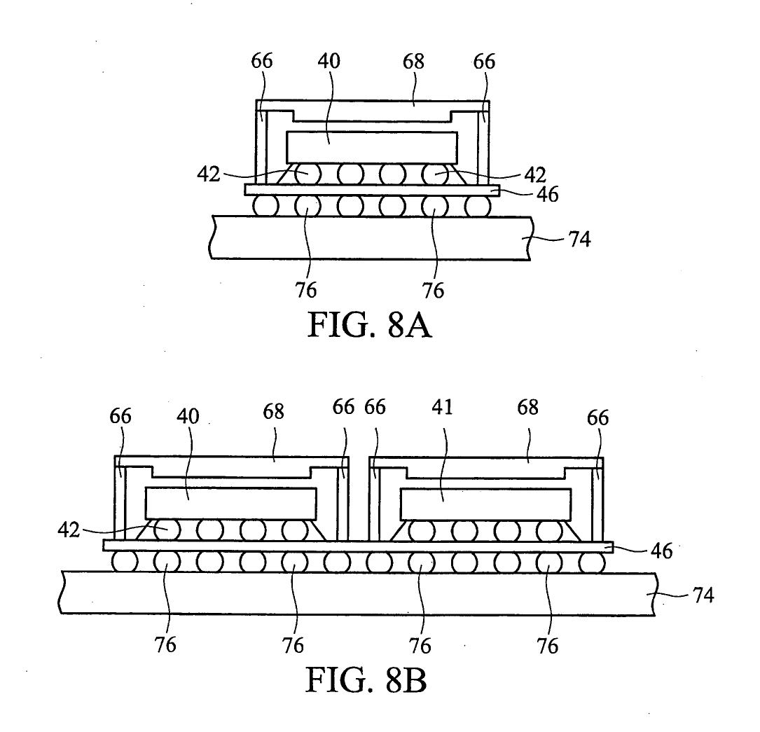

Each of the resulting structures now comprises a die 40 attached to one side of the ultra-thin package substrate 46. The previously formed structure is then assembled on a printed circuit board (PCB) 74 (steps 32 and 34 in FIG. 4), wherein BGA balls 76 may be pre-formed on either PCB 74 or package substrate 46, as shown in FIGS. 8A and 8B. Deep vias 52 are exposed on the other side of the package substrate 46. In the preferred embodiment, the package substrate 46 is mounted on PCB 74 through BGA balls 76, wherein each of the BGA balls 76 is in direct contact with a deep via 52. In other embodiments, the package substrate 46 is mounted on another package substrate, and the resulting structure is packaged in a package, which is then attached on a PCB board through external pins.

Due to the low stress applied on the bumps 42, the preferred embodiments of the present invention are suitable for system in chip (SiP) packaging. FIG. 8B illustrates a package substrate 46 having dies 40 and 41 mounted thereon. The formation process for SiP packaging is similar to the previously discussed embodiment, thus is not repeated herein. Due to the greater sizes, SiP packages typically have greater stresses. The preferred embodiment of the present invention provides a solution for reducing stresses.

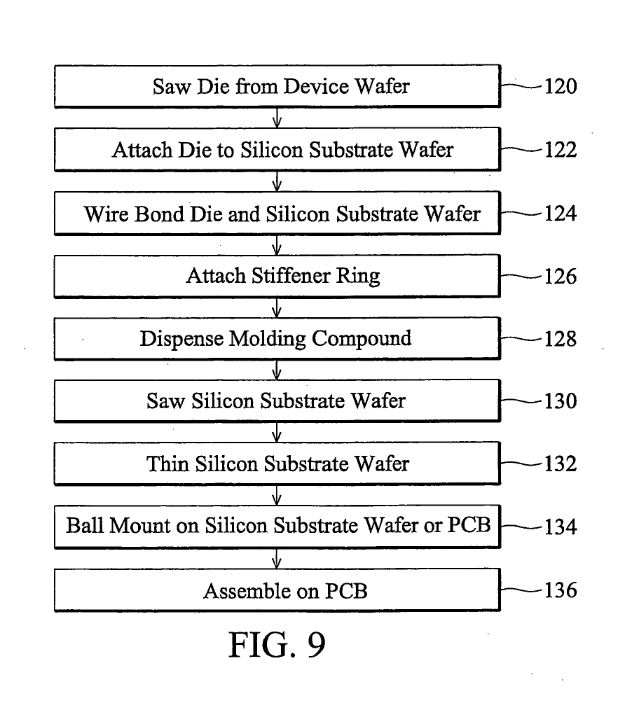

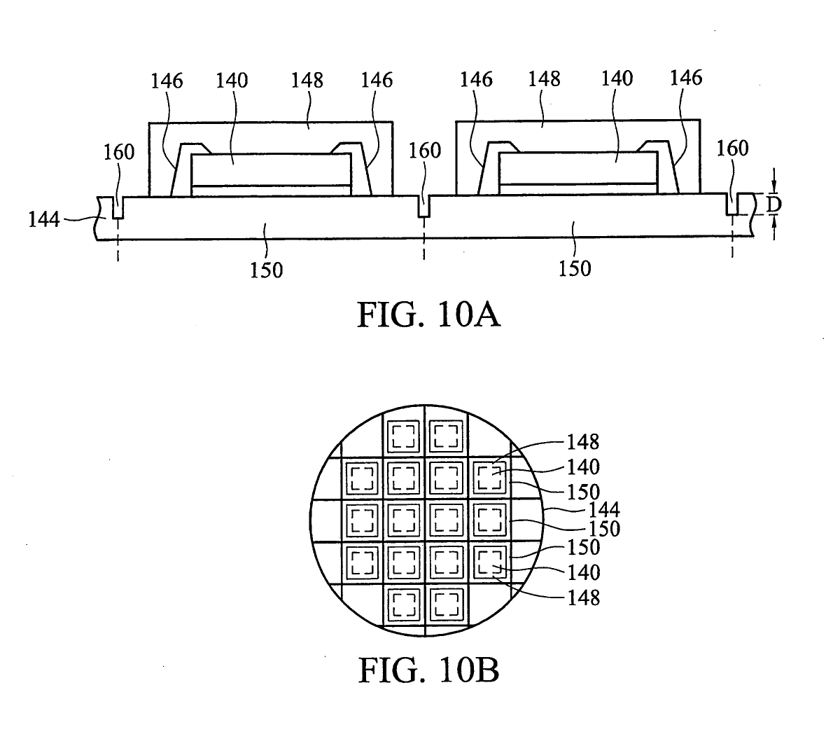

In a variation of the preferred embodiment of the present invention, the ultra-thin package substrate is applied to a wire-bonding package, and a respective flow-chart is shown in FIG. 9. In steps 120 and 122, dies 140 are sawed from a device wafer and attached on a wafer 144, as shown in FIG. 10A. Dies 140 are placed with the back surface attached to the front surface of the wafer 144, and electrical connections between dies 140 and wafer 144 are made through conductive wires 146 (step 124 in FIG. 9).

In the preferred embodiment, stiffener rings are placed encircling dies 140. In other embodiments, stiffener rings are not attached. The reason is that for a chip scale package (CSP), the subsequently dispensed molding compound 148 (step 128 in FIG. 9) provides structural support. Molding compound 148 covers the dies 140 and wires 146. A top view is shown in FIG. 10B. Note that the wafer 144 comprises multiple package substrates 150, and each die 140 is attached to a package substrate 150.

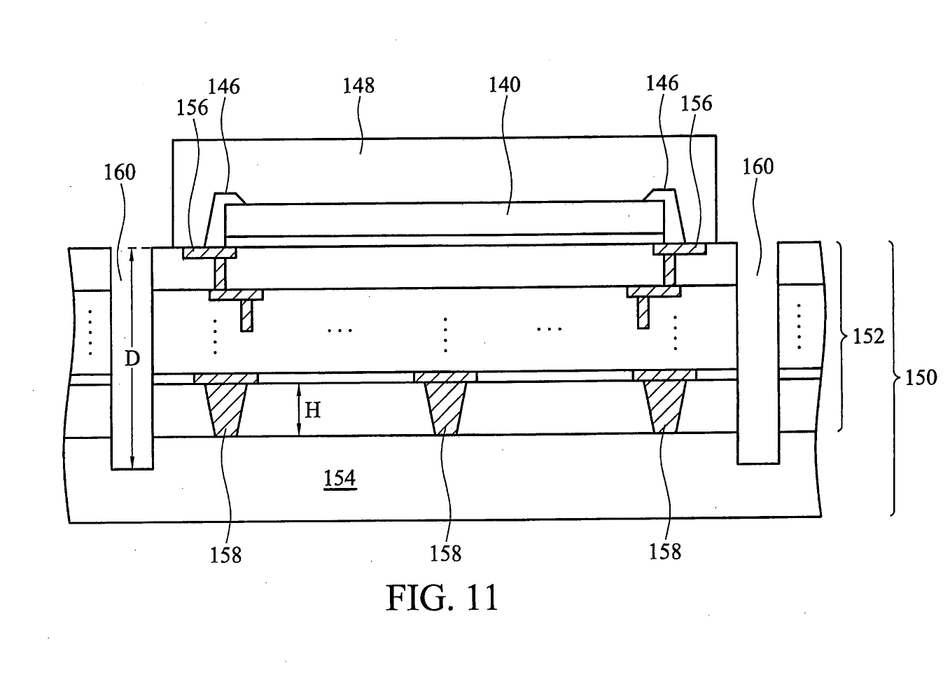

FIG. 11 illustrates a detailed structure of the package substrate 150. Similar to the package substrates used in a flip-chip package, package substrate 150 includes a base layer 154 and an interconnect structure 152, which comprises deep vias 158 connected to pads 156 through layers of interconnections. Package substrates 150 comprise similar materials and are formed using the same methods as package substrates 46 in the previously discussed embodiment. Deep vias 158 preferably have essentially the same height H and pitch as in the flip-chip package. The interconnect structure 152 preferably has a thickness of less than about 50 μm, and more preferably less than about 10 cm.

Referring back to FIG. 10A, trenches 160 are sawed along scribe lines (step 130 in FIG. 9). The trenches 160 preferably have a depth D of less than about 50 μm, or even less than 10 μm, depending on the thickness of the interconnect structure 152. More preferably, the depth D is slightly greater than the thickness of the interconnect structure 152.

The wafer 144 is then protected using a protection tape (not shown) and thinned (step 132 in FIG. 9). The base layer 154 is preferably removed, exposing deep vias 158. Since the interconnect structure 152 has a thickness of less than about 50 μm, the remaining package substrate 150 is ultra-thin with a thickness of less than about 50 μm, and more preferably less than about 10 μm. When base layer 154 is removed, the package substrates 150 are disconnected from each other. After the protection tape is removed, package substrates 150 are separated into individual pieces.

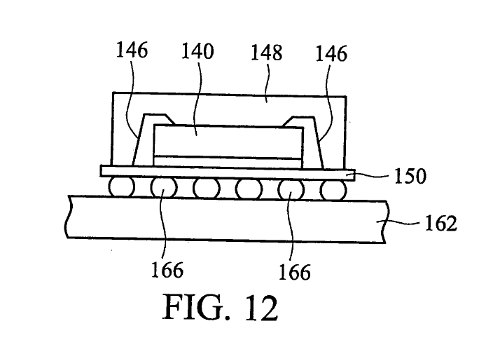

FIG. 12 illustrates the assembly of the previously formed structure to a printed circuit board (PCB) 162 (steps 134 and 136 in FIG. 9), wherein BGA balls 166 may be pre-formed on either PCB 162 or package substrate 150. Each of the resulting structures now comprises a die 140 wire bonded to one side of the package substrate 150. Deep vias 158 (refer to FIG. 11) are exposed on the other side of the package substrates 150. In the preferred embodiment, the package substrate 150 is mounted on PCB 162 through BGA balls 166 wherein each of the BGA balls 166 connects to a deep via 158. In other embodiments, the package substrate 150 is mounted on another package substrate, and the entire structure is packaged in a package. The package is then attached on a PCB board through external pins. In yet other embodiments, an additional die (not shown) is mounted on the package substrate 150 to form a SiP package.

By forming an ultrathin package substrate, the preferred embodiments of the present invention significantly reduce the stresses applied on BGA balls and low-k dielectrics, which are increasingly used in the formation of semiconductor chips. Less stress applied on bumps makes lead-free bumps less likely to crack. The reliability of the packages is thus improved. Electrical performance of the package is also improved due to the flexibility of the routing scheme provided by metallization layers and low-k dielectric layers. The preferred embodiment of the present invention may be used for system in package (SiP) to reduce stresses.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a semiconductor package assembly, the method comprising:
providing a package substrate comprising a base material;
forming an interconnect structure overlying the package substrate, wherein the interconnect structure comprises deep vias at the bottom of the interconnect structure;
attaching at least one chip to a first surface of the package substrate;
thinning the package substrate from a second surface opposing the first surface, wherein at least a substantial portion of the base material is removed; and
attaching ball grid array (BGA) balls to the deep vias exposed on the second surface of the package substrate after the step of thinning the package substrate.

2. The method of claim 1, wherein, before the step of thinning the package substrate, the package substrate is in a form of a wafer.

3. The method of claim 1, wherein the base material comprises silicon.

4. The method of claim 1, wherein the step of forming the interconnect structure comprises:
forming a dielectric layer over the base material;
forming deep vias in the dielectric layer, wherein the deep vias extend from a top surface to a bottom surface of the dielectric layer;
forming a plurality of additional dielectric layers over the dielectric layer;
forming a plurality of metallization layers and a plurality of vias in the additional dielectric layers, wherein the metallization layers and vias are interconnected and connected to the deep vias; and
forming a plurality of contact pads electrically connected to the metallization layers, wherein the contact pads are electrically connected to the at least one chip.

5. The method of claim 1, wherein the step of forming the interconnect structure comprises:
forming deep vias in the base material, wherein the base material is selected from a group consisting essentially of semiconductor materials and dielectric materials;
forming a plurality of additional dielectric layers over the dielectric layer;
forming a plurality of metallization layers and a plurality of vias in the additional dielectric layers, wherein the metallization layers and vias are interconnected and connected to the deep vias; and
forming a plurality of contact pads electrically connected to the metallization layers, wherein the contact pads are electrically connected to the at least one chip.

6. The method of claim 1, wherein the step of attaching the at least one chip to the first surface of the package substrate comprises flip bonding.

7. The method of claim 1, wherein the step of attaching the at least one chip to the first surface of the package substrate comprises wire bonding.

8. The method of claim 1 further comprising sawing trenches on the first surface of the package substrate and along scribe lines, wherein the trenches have a depth less than a thickness of the package substrate and greater than a thickness of the interconnect structure.

9. The method of claim 8, wherein the depth of the trenches is less than about 50 μm.

10. The method of claim 1 further comprising attaching a stiffener ring and a heat spreader to the at least one chip.

11. A method of forming a semiconductor package assembly, the method comprising:
providing a wafer comprising a base material, wherein the wafer comprises a plurality of package substrates defined by scribe lines;
forming an interconnect structure overlying each of the package substrates comprising:
forming deep vias adjacent to a top surface of the base material;
forming a plurality of dielectric layers over the deep vias;
forming a plurality of metallization layers and a plurality of vias connected to the metallization layers in the dielectric layers, wherein the metallization layers and the vias are connected to the deep vias; and
forming a plurality of contact pads connected to a top metallization layer in the metallization layers;
attaching a semiconductor chip to contact pads on a first surface of each of the package substrates;
sawing the package substrates on a first surface of the wafer along the scribe lines to form trenches, wherein the trenches have a depth less than a thickness of the package substrates and greater than a thickness of the interconnect structure;
applying a protection tape on the first surface of the wafer;
thinning the wafer from a second surface opposite the first surface by removing at least a portion of the base material and exposing the deep vias, wherein the package substrates are separated after thinning;
removing the protection tape; and
attaching BGA balls to deep vias of the package substrates.

12. The method of claim 11, wherein the semiconductor chip is attached to the contact pads through wire bonding.

13. The method of claim 11, wherein the semiconductor chip is attached to the contact pads through flip-chip bonding.

14. The method of claim 11, wherein the interconnect structure has a thickness of less than about 50 μm.

15. The method of claim 11, wherein the step of thinning the wafer comprises a method selected from the group consisting essentially of etching, polishing and chemical mechanical polishing.

16. The method of claim 11, wherein the step of forming the deep vias comprises forming deep vias from a top surface of the base material into the base material, wherein the base material is selected from the group consisting essentially of semiconductor materials and dielectric materials.

17. The method of claim 11, wherein the step of forming the deep vias comprises:
forming a dielectric layer over the base material; and
forming the deep vias extending from a top surface of the dielectric layer to a bottom surface of the dielectric layer.

18. A semiconductor package assembly comprising:
a die mounted on a first surface of a package substrate, wherein the package substrate has a thickness of less than about 50 μm, and wherein the package substrate comprises an interconnect structure having at least two conductive layers in dielectric layers.

19. The semiconductor package assembly of claim 18, wherein the thickness of the package substrate is less than about 10 μm.

20. The semiconductor package assembly of claim 18, wherein the die comprises at least one low-k dielectric layer with a dielectric constant of less than about 3.0.

21. The semiconductor package assembly of claim 18, wherein the package substrate is substantially free of semiconductor materials and organic materials.

22. The semiconductor package assembly of claim 18, wherein the die is flip mounted on the package substrate through bumps.

23. The semiconductor package assembly of claim 22, wherein the bumps have a lead concentration of less than about five percent.

24. The semiconductor package assembly of claim 18, wherein the interconnect structure comprises dual damascene or single damascene structures.

25. The semiconductor package assembly of claim 18, wherein the interconnect structure comprises:
a base layer;
deep vias in the base layer, wherein the deep vias are exposed through a second surface of the package substrate opposite the first surface;
a plurality of dielectric layers over the base layer;
a plurality of metallization layers and a plurality of vias connected to the metallization layers in the dielectric layers, wherein the metallization layers are interconnected and connected to the deep vias; and
a plurality of contact pads connected to the metallization layers, wherein the contact pads are electrically connected to the die through conductive wires or bumps.

26. The semiconductor package assembly of claim 25, wherein the deep vias are further attached to BGA balls.

27. The semiconductor package assembly of claim 25, wherein the base layer is a semiconductor layer.

28. The semiconductor package assembly of claim 25, wherein the base layer is a dielectric layer.

29. A semiconductor package assembly comprising:
a die mounted on a first surface of a package substrate, wherein the die comprises at least one low-k dielectric layer having a dielectric constant of less than about 3.0; and
BGA balls attached on a second surface of the package substrate opposing the first surface, wherein the package substrate has a thickness of less than about 50 μm and comprises:
a dielectric layer;
deep vias in the dielectric layer, wherein the deep vias are attached to the BGA balls;
a plurality of dielectric layers over the dielectric layer;
a plurality of metallization layers and a plurality of vias connected to the metallization layers in the dielectric layers, wherein the metallization layers are interconnected and connected to the deep vias; and
a plurality of contact pads connected to the metallization layers, wherein the contact pads are electrically connected to the die through conductive wires or bumps.

30. The semiconductor package assembly of claim 29, wherein the thickness of the package substrate is less than about 10 μm.

31. The semiconductor package assembly of claim 29, wherein the die is flip-bonded to the package substrate.

32. The semiconductor package assembly of claim 29, wherein the die is wire-bonded to the package substrate.

33. The semiconductor package assembly of claim 29 further comprising a stiffener ring encircling the die and a heat spreader over the die.
